(19) United States
(12) Patent Application Publication
(10) Pub. No.: US 2019/0357387 A1
(43) Pub. Date: Nov. 21, 2019

(54) THERMAL CONTROL WITH VAPOR AND ISOLATION CHAMBERS

(71) Applicant: HEWLETT-PACKARD DEVELOPMENT COMPANY, L.P., Spring, TX (US)

(72) Inventors: Alan D. Peterson, Houston, TX (US); David Isaac Blatt, Spring, TX (US); Michael James Pescetto, Houston, TX (US)

(73) Assignee: HEWLETT-PACKARD DEVELOPMENT COMPANY, L.P., Spring, TX (US)

(21) Appl. No.: 16/463,292

(22) PCT Filed: Feb. 3, 2017
(86) PCT No.: PCT/US2017/016556

§ 371 Date: May 22, 2019

(51) Int. Cl. H05K 7/20; G06F 1/20

(52) U.S. Cl. CPC H05K 7/20327; G06F 1/203

(57) ABSTRACT

In some examples, a thermal control device includes a vapor chamber comprising a fluid to transport heat from a first portion of the vapor chamber to a second portion of the vapor chamber, and an isolation chamber adjacent the vapor chamber and fluidically isolated from the vapor chamber, the isolation chamber evacuated to a pressure less than atmospheric pressure to thermally isolate at least a portion of the vapor chamber.

### BACKGROUND

An electronic device can include an electronic component that produces heat during operation of the electronic component. A thermal dissipation device can be included in the electronic device to dissipate heat produced by the electronic component away from the electronic component.

### BRIEF DESCRIPTION OF THE DRAWINGS

Some implementations of the present disclosure are described with respect to the following figures.

FIG. 1 is a schematic sectional view of a thermal control device according to some examples.

FIG. 2 is a schematic sectional view of a thermal control device according to further examples.

FIG. 3 is a schematic sectional view of an electronic device including a thermal control device according to some examples.

FIG. 4 is a flow diagram of a process of making a thermal control device, according to some examples.

FIG. 5 illustrates manufacturing stages for making a thermal control device according to some examples.

### DETAILED DESCRIPTION

In the present disclosure, use of the term “a,” “an”, or “the” is intended to include the plural forms as well, unless the context clearly indicates otherwise. Also, the term “includes,” “including,” “comprises,” “comprising,” “have,” or “having” when used in this disclosure specifies the presence of the stated elements, but do not preclude the presence or addition of other elements.

During use, an electronic device can be in contact with a human user. For example, a handheld electronic device can be held in a hand (or hands) of the user. Examples of handheld electronic devices include any or some combination of the following: a smartphone, a tablet computer, a game appliance, or any other device that are held by a user's hand(s) during use. Other examples of electronic devices that can be in contact with a part of a user during use can include: a wearable device (such as a smart watch, smart eyeglasses, a head-mounted device, and so forth), a notebook computer, and so forth. Although specific examples of electronic devices are listed above, it is noted that in further examples, there can be other examples of electronic devices that users make contact with during use.

A skin temperature of an electronic device can refer to a temperature of an outer surface of an external housing of the electronic device. If the skin temperature of the electronic device rises too high during operation of the electronic device, a user may experience discomfort or sustain injury if the user makes contact with the part of the external housing that has the elevated skin temperature.

In accordance with some implementations of the present disclosure, a thermal control device is provided that is able to perform: (1) heat dissipation to remove heat away from an electronic component (to protect the electronic component from overheating), and (2) thermal isolation to prevent or reduce heat transfer to the outer surface of an external housing of an electronic device.

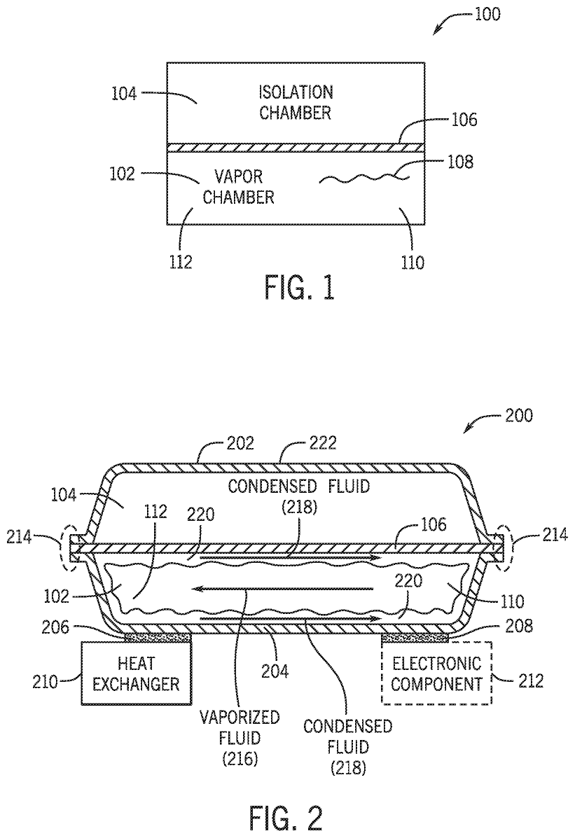

FIG. 1 is a schematic side view of a thermal control device 100 that includes a vapor chamber 102 and an isolation chamber 104 that is adjacent the vapor chamber 102. The isolation chamber 104 is “adjacent” the vapor chamber 102 if the isolation chamber 104 is positioned next to the vapor chamber 102. In some examples, the isolation chamber 104 and the vapor chamber 102 are integrally formed as part of the thermal control device 100. In other examples, the isolation chamber 104 and the vapor chamber 102 can be separate components that are attached together. In yet further examples, the isolation chamber 104 and the vapor chamber 102 are separate components that can be brought into contact with one another when assembled into an electronic device.

A barrier 106 is provided between the vapor chamber 102 and the isolation chamber 104 to fluidically isolate the isolation chamber 104 from the vapor chamber 102. The isolation chamber 104 is fluidically isolated from the vapor chamber 102 if fluid in the vapor chamber 112, including a working fluid 108, cannot pass to the isolation chamber 104. The barrier 106 can be formed of a metal, such as titanium, copper, or any other material that is impermeable to a fluid, including gas and/or liquid.

The working fluid 108 in the vapor chamber 102 is used to transport heat from a first portion 110 of the vapor chamber 102 to a second portion 112 of the vapor chamber. Examples of the working fluid 108 can include any or some combination of the following: water, ammonia, acetone, nitrogen, methanol, or any other fluid that vaporizes when heated and condenses when cooled. The presence of the barrier 106 prevents the working fluid 108 from entering the isolation chamber 104.

The isolation chamber 104 is evacuated to a pressure that is less than atmospheric pressure, which is the pressure of the atmosphere in which the thermal control device 100 is located. More specifically, the isolation chamber 104 can be evacuated to a vacuum. The isolation chamber 104 is considered to contain a vacuum if, during manufacture of the thermal control device 100, a fluid (gas and/or liquid) in the isolation chamber 104 is evacuated, which causes the pressure of the isolation chamber 104 to drop below the atmospheric pressure. It is noted that after evacuation of the isolation chamber 104, some small amount of a fluid (e.g., gas) may remain in the isolation chamber 104. However, in some examples, the isolation chamber 104 can be free of any liquid.

Whereas the vapor chamber 102 is filled with a sufficient amount of the working fluid 108 to allow the vapor chamber 102 to perform heat transfer between different locations (for the purpose of dissipating heat from a heat-producing component thermally contacted to the vapor chamber 102), fluid is evacuated from the isolation chamber 104 to prevent or reduce heat transfer through the isolation chamber 104.

The isolation chamber 104 is to thermally isolate at least a portion of the vapor chamber 102, such that heat in this portion of the vapor chamber 102 is thermally isolated by the isolation chamber 104 from another region. For example, the isolation chamber 104 provides thermal isolation between the vapor chamber 102 and a surface that is in thermal conductive contact with the isolation chamber 104. This surface can be an external surface of an electronic device in which the thermal control device 100 is provided, or the surface can be a different surface.

FIG. 2 is a schematic sectional view of a thermal control device 200 according to further examples. The thermal control device 200 includes a housing portion 202 and a housing portion 204 that are attached together to form a housing of the thermal control device 200.

The thermal control device 200 includes the vapor chamber 102 and the isolation chamber 104. In addition the thermal control device 200 includes a thermal interface 206 that is thermally contacted to the outer surface of the housing portion 204 near the second portion 112 of the vapor chamber 102, and a thermal interface 208 thermally contacted to the outer surface of the housing portion 204 near the first portion 110 of the vapor chamber 102. The thermal interface 206 or 208 can be formed of a thermally conductive material, such as thermal paste, a thermal adhesive, or any other layer through which heat can be conducted.

The thermal control device 200 also includes a heat exchanger 210 that is thermally contacted to the thermal interface 206. The heat exchanger 210 can include a heat spreader to spread heat away from the vapor chamber 102. For example, a heat spreader can include a heat sink that has fins or other types of heat dissipation surfaces. In some examples, the heat exchanger 210 can also include an airflow generator, such as a fan, to produce an airflow to carry heat away from the vapor chamber 102. Heat transferred to the second portion 112 of the vapor chamber 102 is communicated through the thermal interface 206 to the heat exchanger 210, which dissipates the heat away from the vapor chamber 102. The vapor chamber 102 is in thermal conductive contact with the heat exchanger 210, since heat transfer is possible between the vapor chamber 102 and the heat exchanger 210 through the thermal interface 206.

The thermal interface 208 is thermally contacted to an electronic component 212 that can produce heat during operation of the electronic component 212. Heat from the electronic component 212 is passed through the thermal interface 208 to the vapor chamber 102. For example, the electronic component 212 can include a processor, such as a microprocessor, a microcontroller, a programmable integrated circuit device, a programmable gate array, and so forth. Alternatively, the electronic component 212 can include a memory device, an input/output (I/O) device, or any other type of electronic component that can produce heat during operation. The vapor chamber 102 is in thermal conductive contact with the electronic component 212, since heat transfer is possible between the vapor chamber 102 and the electronic component 212 through the thermal interface 208.

It is noted that the electronic component 212 is not part of the thermal control device 200, and thus is shown in dashed profile.

The housing portions 202 and 204 are attached together at attachment points 214. In some examples, the housing portions 202 and 204 can be attached together by welding, by crimping, by soldering, by brazing, by use of adhesives, by bolting, or by any other attachment mechanism. Note that the barrier 106 can also be attached together with the housing portions 202 and 204 at attachment points 214. Attaching the housing portions 202 and 204 together seals the vapor chamber 102 and the isolation chamber 104.

The vapor chamber 102 includes a path through which vaporized fluid 216 can flow from the first portion 110 of the vapor chamber 102 to the second portion 112 of the vapor chamber 102. The vaporized fluid 216 is generated when heat from the electronic component 212 vaporizes a liquid that is located at the first portion 110 of the vapor chamber 102. The path through which the vaporized fluid 216 can flow can include a channel (or multiple channels).

The vaporized fluid 216 is condensed at the second portion 112 of the vapor chamber 102, due to cooling caused by the heat exchanger 210. The condensed fluid 218 (which is in liquid form) is carried by capillary action along a wick structure 220 that lines an inner surface of the vapor chamber 102. In examples according to FIG. 2, the wick structure 220 can be attached to a surface of the barrier 106 and an inner surface of the housing portion 204. In other examples, the wick structure 220 can be attached to just the inner surface of the housing portion 204, and not to the surface of the barrier 106.

The wick structure 220 includes small fluid paths that allow for the condensed fluid 218 to be transported by capillary action along the small fluid paths. When the condensed fluid 218 reaches the first portion 110 of the vapor chamber 102, the condensed fluid 218 vaporizes to become the vaporized fluid 216 in response to heat from the electronic component 212,

The presence of the isolation chamber 104 serves to provide thermal isolation between the chamber 102 and an external surface 222 of the housing portion 104 that is farthest away from the vapor chamber 102. In some examples, the external surface 222 of the housing portion 202 can form an external surface of the electronic device in which the thermal control device 200 is located. Alternatively, the external surface 222 of the housing portion 202 can make contact with the external housing of the electronic device. The thermal isolation provided by the isolation chamber 104 allows the external surface 222 of the housing portion 204 to remain at a lower temperature than the vapor chamber 102, which reduces the likelihood of an elevated skin temperature of an electronic device that can cause discomfort or injury to a user of the electronic device.

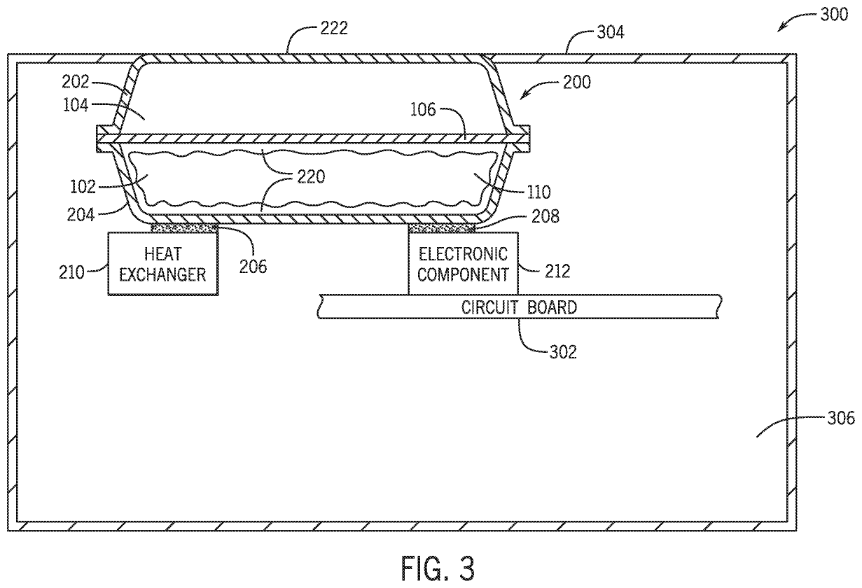

FIG. 3 is a schematic sectional view of an electronic device 300 that includes the thermal control device 200 and other components, including the electronic component 212 and a circuit board 302 on which the electronic component 212 is mounted. Additional electronic components (not shown) can also be mounted on the circuit board 302, where such additional electronic components can also be thermally contacted to the vapor chamber 102 (or to another thermal control device not shown).

Components shown in FIG. 3 that are in common with the components of FIG. 2 are assigned the same reference numerals. The electronic device 300 includes an external housing 304, which defines an inner chamber 306 in which the thermal control device 200, the electronic component 212, and the circuit board 302 are located. In examples according to FIG. 3, the external surface 222 of the housing portion 202 of the thermal control device 200 forms a part of the external surface of the electronic device 300. In other examples, the housing portion 202 of the thermal control device 200 is not exposed outside the electronic device housing 304, but instead, the external surface 222 of the housing portion 202 of the thermal control device 200 can be contacted to the external housing 304 of the electronic device 300.

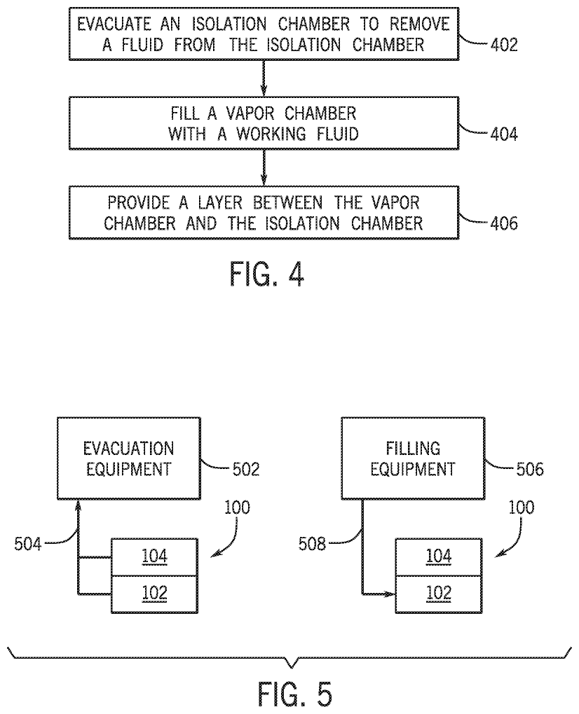

FIG. 4 is a flow diagram of a process of making a thermal control device (e.g., 100 or 200 in FIG. 1 or 2), according to some examples. The process of FIG. 4 includes evacuating (at 402) an isolation chamber (e.g., the isolation chamber 104) to remove fluid from the isolation chamber.

The process of FIG. 4 further includes filling (at 404) a vapor chamber (e.g., the vapor chamber 102) with a working fluid for transporting heat from a first portion of the vapor chamber to a second portion of the vapor chamber. The process further includes providing (at 406) a layer (e.g., the barrier 106) between the vapor chamber and the isolation chamber, the layer fluidically isolating the isolation chamber from the vapor chamber.

In addition, although not shown in FIG. 4, the process can further evacuate the vapor chamber to remove a fluid from the vapor chamber prior to filling (at 404) the vapor chamber with the working fluid. The evacuating of the isolation chamber (at 402) and the evacuating of the vapor chamber can be performed together.

Further, the process attaches housing portions together to form a housing that defines the vapor chamber and the isolation chamber, where the layer is provided within the housing. In some examples, the layer can be attached to the housing portions. The attachment of the housing portions together seals the vapor chamber and the isolation chamber.

FIG. 5 is a schematic diagram that shows various manufacturing stages for making the thermal control device 100 according to some examples. The manufacturing stages include manufacturing equipment, such as evacuation equipment 502 and filling equipment 506. There are other manufacturing stages (and their respective manufacturing equipment) for making a thermal control device that are not shown in FIG. 5.

The evacuation equipment 502 is used to evacuate the vapor chamber 102 and the isolation chamber 104 of the thermal control device. For example, the evacuation equipment 502 can be connected to inlet ports of the vapor chamber 102 and the isolation chamber 104 over a fluid path 504. The evacuation equipment 502 can be activated to evacuate any fluid inside the vapor chamber 102 and isolation chamber 104 along the fluid path 504. For example, the evacuation equipment 502 can include a pump to draw down pressure that causes fluids inside the vapor chamber 102 and the isolation chamber 104 to flow out of the chambers and along the path 504 to a fluid exit (not shown). In some examples, the evacuation equipment 502 is able to evacuate the vapor chamber 102 and the isolation chamber 104 to a vacuum.

In accordance with some examples, the vapor chamber 102 and the isolation chamber 104 can be evacuated together as part of the same evacuation operation performed by the evacuation equipment 502. This simplifies the manufacturing process of the thermal control device 100 by avoiding the use of separate operations to evacuate the vapor and isolation chambers. By simplifying the manufacturing process, the cost associated with making the thermal control device 100 can be reduced.

Once the isolation chamber 104 has been evacuated to a vacuum, the inlet port to the isolation chamber 104 can be plugged to seal the isolation chamber 104. Next, the filling equipment 506 is used to inject a working fluid along a fluid path 508 through the inlet port of the vapor chamber 102, to partially fill the vapor chamber 102 with the working fluid. Once the vapor chamber 102 has been filled with the working fluid, the inlet port to the vapor chamber 102 can be plugged to seal the vapor chamber 102.

Although FIG. 5 shows just the evacuation equipment 502 and the filling equipment 506, it is noted that the manufacturing process to make the thermal control device 100 can involve other manufacturing equipment, including equipment to form the housing portions of the thermal control device 100 and to add the barrier 106, equipment to attach the housing portions and barrier together, and so forth.

In addition to being relatively cost effective to make, the thermal control device 100 also does not add substantial weight to an electronic device in which the thermal control device 100 is included. The isolation chamber 104 is effectively an empty container with a very small amount of fluid (e.g., trace amounts of fluid), and thus would not add substantially to the overall weight of the thermal control device as compared to a thermal control device that omits the isolation chamber 104 but includes other components of the thermal control device (such as the vapor chamber 102, the heat exchanger 210, etc.).

In the foregoing description, numerous details are set forth to provide an understanding of the subject disclosed herein. However, implementations may be practiced without some of these details. Other implementations may include modifications and variations from the details discussed above. It is intended that the appended claims cover such modifications and variations.

What is claimed is:

1. A thermal control device comprising:
a vapor chamber comprising a fluid to transport heat from a first portion of the vapor chamber to a second portion of the vapor chamber; and
an isolation chamber adjacent the vapor chamber and fluidically isolated from the vapor chamber, the isolation chamber evacuated to a pressure less than atmospheric pressure to thermally isolate at least a portion of the vapor chamber.

2. The thermal control device of claim 1, further comprising a housing containing the vapor chamber and the isolation chamber, and a layer between the vapor chamber and the vacuum chamber, the layer impermeable to fluid.

3. The thermal control device of claim 2, wherein the layer comprises a metal.

4. The thermal control device of claim 1, wherein the isolation chamber is free of a liquid.

5. The thermal control device of claim 1, wherein the fluid in the vapor chamber is to vaporize in response to heat produced by a heat producing component in thermal conductive contact with the first portion of the vapor chamber, and the vaporized fluid is to condense at the second portion of the vapor chamber, and wherein the condensed fluid is to be transported by capillary action from the second portion to the first portion.

6. The thermal control device of claim 1, wherein the isolation chamber provides thermal isolation between the vapor chamber and a surface in thermal conductive contact with the isolation chamber.

7. The thermal control device of claim 1, further comprising:
a heat exchanger in thermal conductive contact with the second portion of the vapor chamber.

8. A method of making a thermal control device, comprising:
evacuating an isolation chamber to remove fluid from the isolation chamber;
filling a vapor chamber with a working fluid for transporting heat from a first portion of the vapor chamber to a second portion of the vapor chamber; and
providing a layer between the vapor chamber and the isolation chamber, the layer fluidically isolating the isolation chamber from the vapor chamber.

9. The method of claim 8, further comprising:
evacuating the vapor chamber to remove a fluid from the vapor chamber; and
after the evacuating of the vapor chamber, performing the filling of the vapor chamber with the working fluid.

10. The method of claim 9, wherein the evacuating of the isolation chamber and the evacuating of the vapor chamber are performed together.

11. The method of claim 8, further comprising:
attaching housing portions together to form a housing that defines the vapor chamber and the isolation chamber, the layer being provided within the housing.

12. The method of claim 11, further comprising:
attaching the layer to the housing portions.

13. The method of claim 11, wherein attaching the housing portions together seals the vapor chamber and the isolation chamber.

14. An electronic device comprising:
an electronic component; and
a thermal control device in thermal conductive contact with the electronic component, the thermal control device comprising:
a vapor chamber comprising a fluid to transport heat from a first portion of the vapor chamber to a second portion of the vapor chamber; and
an isolation chamber adjacent the vapor chamber and fluidically isolated from the vapor chamber, the isolation chamber containing a vacuum and to thermally isolate at least a portion of the vapor chamber; and
a heat exchanger in thermal contact with the thermal control device.

15. The electronic device of claim 14, wherein a surface of the thermal control device forms an outer housing surface of the electronic device.
